(19) United States
(12) Patent Application Publication
(10) Pub. No.: US 2025/0357715 A1
(43) Pub. Date: Nov. 20, 2025

(54) GAS LASER DEVICE AND ELECTRONIC DEVICE MANUFACTURING METHOD

(71) Applicant: Gigaphoton Inc., Tochigi (JP)

(72) Inventors: Tatsuo YAMAGUCHI, Tochigi (JP); Hirotaka MIYAMOTO, Tochigi (JP)

(73) Assignee: Gigaphoton Inc., Tochigi (JP)

(21) Appl. No.: 19/291,550

(22) Filed: Aug. 5, 2025

Related U.S. Application Data
(63) Continuation of application No. PCT/JP2023/009951, filed on Mar. 14, 2023.

(51) Int. Cl. H01S 3/034; G03F 7/20; H01S 3/038; H01S 3/083; H01S 3/102

(52) U.S. Cl. CPC H01S 3/034; G03F 7/20; H01S 3/038; H01S 3/0835; H01S 3/1024

(57) ABSTRACT

A gas laser device configured to amplify, using an amplifier, laser light output from a laser oscillator and output the laser light. The amplifier includes a chamber device including a pair of discharge electrodes, and being configured to amplify the laser light by a voltage being applied between the pair of discharge electrodes; a resonator causing the laser light output from the chamber device to resonate; and a beam expander. The resonator includes an output coupling mirror causing a part of the laser light to be transmitted therethrough, and another part to be reflected back into the chamber device, and the beam expander including a convex mirror reflecting the laser light to expand a beam width of the laser light, and a concave mirror reflecting the laser light toward the output coupling mirror to collimate the laser light so that the expanded beam width of the laser light becomes constant.

### CROSS-REFERENCE TO RELATED APPLICATIONS

The present application is a continuation application of International Application No. PCT/JP2023/009951, filed on Mar. 14, 2023, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248.0 nm and an ArF excimer laser device for outputting laser light having a wavelength of about 193.4 nm are used.

The KrF excimer laser device and the ArF excimer laser device each have a large spectral line width of about 350 μm to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. 2011-233918
Patent Document 2: Japanese Patent Application Publication No. H4-239784
Patent Document 3: Japanese Patent Application Publication No. H4-301613

### SUMMARY

A gas laser device according to an aspect of the present disclosure is a gas laser device configured to amplify, using an amplifier, laser light output from a laser oscillator and output the laser light. Here, the amplifier includes a chamber device including a pair of discharge electrodes facing each other and arranged at an internal space thereof through which the laser light from the laser oscillator passes and in which a laser gas is filled, and configured to amplify the laser light from the laser oscillator by a voltage being applied between the pair of discharge electrodes; a resonator configured to cause the laser light output from the chamber device to resonate between both sides sandwiching the chamber device; and a beam expander. The resonator includes an output coupling mirror arranged on one side of the sides sandwiching the chamber device, and is configured to cause a part of the laser light output from the chamber device to be transmitted therethrough, and another part of the laser light output from the chamber device to be reflected back into the chamber device. The beam expander is arranged between the chamber device and the output coupling mirror, and includes a convex mirror including a reflection surface reflecting the laser light output from the chamber device to expand a beam width of the laser light, and a concave mirror including a reflection surface reflecting the laser light reflected by the convex mirror toward the output coupling mirror to collimate the laser light so that the expanded beam width of the laser light becomes constant.

An electronic device manufacturing method according to an aspect of the present disclosure includes generating pulse laser light using a gas laser device, outputting the pulse laser light to an exposure apparatus, and exposing a photosensitive substrate to the pulse laser light in the exposure apparatus to manufacture an electronic device. Here, the gas laser device is configured to amplify, using an amplifier, laser light output from a laser oscillator and output the laser light. The amplifier includes a chamber device including a pair of discharge electrodes facing each other and arranged at an internal space thereof through which the laser light from the laser oscillator passes and in which a laser gas is filled, and being configured to amplify the laser light from the laser oscillator by a voltage being applied between the pair of discharge electrodes; a resonator configured to cause the laser light output from the chamber device to resonate between both sides sandwiching the chamber device; and a beam expander. The resonator includes an output coupling mirror arranged on one side of the sides sandwiching the chamber device, and is configured to cause a part of the laser light output from the chamber device to be transmitted therethrough, and another part of the laser light output from the chamber device to be reflected back into the chamber device. The beam expander is arranged between the chamber device and the output coupling mirror, and includes a convex mirror configured to reflect the laser light output from the chamber device to expand a beam width of the laser light, and a concave mirror configured to reflect the laser light reflected by the convex mirror toward the output coupling mirror to collimate the laser light so that the expanded beam width of the laser light becomes constant.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire gas laser device of a comparative example.

FIG. 3 is a schematic view showing a schematic configuration example of an amplifier of a first embodiment.

FIG. 4 is a diagram showing a state of preparation before an output coupling mirror is arranged.

FIG. 5 is a diagram showing a state of the output coupling mirror being arranged.

FIG. 6 is a diagram showing a state of a beam expander being arranged.

FIG. 7 is a schematic view showing a schematic configuration example of the amplifier of a second embodiment in the same manner as in FIG. 3.

FIG. 8 is a diagram showing the beam expander shown in FIG. 7 as viewed from a chamber device side.

FIG. 9 is a diagram showing a state of a convex mirror and a concave mirror being arranged on a base member.

FIG. 10 is a diagram showing the beam expander in a modification of the second embodiment viewed from the chamber device side.

FIG. 11 is a schematic view showing a schematic configuration example of the amplifier of a third embodiment in the same manner as in FIG. 3.

FIG. 12 is a diagram showing a state of the output coupling mirror, the convex mirror, and the concave mirror being arranged on the base member.

FIG. 13 is a diagram showing a state of the beam expander being arranged.

FIG. 14 is a schematic view showing a schematic configuration example of the amplifier of a modification of the third embodiment in the same manner as in FIG. 3.

FIG. 15 is a schematic view showing a schematic configuration example of the amplifier of a fourth embodiment in the same manner as in FIG. 3.

### DESCRIPTION OF EMBODIMENTS

1. Description of electronic device manufacturing apparatus used in exposure process for electronic device
2. Description of gas laser device of comparative example
   2.1 Configuration
   2.2 Operation
   2.3 Problem
3. Description of gas laser device of first embodiment
   3.1 Configuration
   3.2 Operation
   3.3 Effect
4. Description of gas laser device of second embodiment
   4.1 Configuration
   4.2 Effect
5. Description of gas laser device of third embodiment
   5.1 Configuration
   5.2 Effect
6. Description of gas laser device of fourth embodiment
   6.1 Configuration
   6.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus Used in Exposure Process for Electronic Device

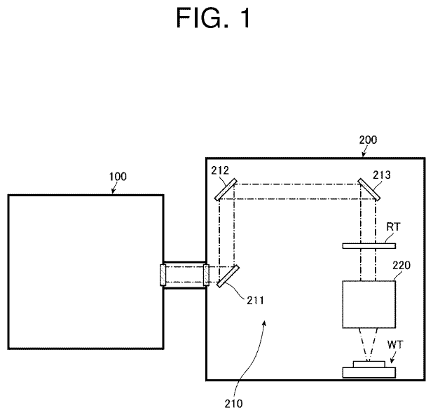

FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device of a comparative example will be described. The comparative example of the present disclosure is an example recognized by the applicant as known only by the applicant, and is not a publicly known example admitted by the applicant.

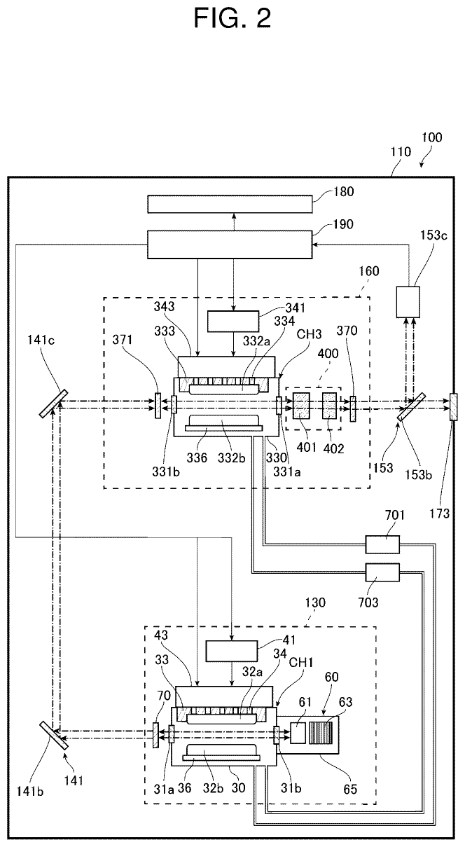

FIG. 2 is a schematic view showing a schematic configuration example of the entire gas laser device 100 of the present example. The gas laser device 100 is, for example, an ArF excimer laser device using a mixed gas including argon (Ar), fluorine (F₂), and neon (Ne). The gas laser device 100 outputs laser light having a center wavelength of about 193.4 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248.0 nm. The mixed gas containing Ar, Fc, and Ne which is a laser medium and the mixed gas containing Kr, F₂, and Ne which is a laser medium may be each referred to as a laser gas. In the mixed gas used in each of the ArF excimer laser device and the KrF excimer laser device, helium (He) may be used instead of Ne.

The gas laser device 100 of the present example includes a housing 110, a laser oscillator 130 that is a master oscillator arranged at the internal space of the housing 110, an optical transmission unit 141, an amplifier 160 that is a power oscillator, a detection unit 153, a display unit 180, a processor 190, a laser gas exhaust device 701, and a laser gas supply device 703 as a main configuration.

The laser oscillator 130 includes a chamber device CH1, a charger 41, a pulse power module 43, a line narrowing module 60, and an output coupling mirror 70 as a main configuration.

In FIG. 2, the internal configuration of the chamber device CH1 is shown as viewing from a direction substantially perpendicular to the travel direction of the laser light. The chamber device CH1 includes a housing 30, a pair of windows 31a, 31b, a pair of electrodes 32a, 32b, an insulating portion 33, a feedthrough 34, and an electrode holder portion 36 as a main configuration.

The housing 30 is supplied with the laser gas from the laser gas supply device 703 to the internal space of the housing 30 via a pipe, and the internal space is filled with the laser gas. The internal space is a space in which light is generated by excitation of the laser medium in the laser gas. This light travels to the windows 31a, 31b.

The window 31a is arranged at a wall surface of the housing 30 on the front side in the travel direction of the laser light from the gas laser device 100 to the exposure apparatus 200, and the window 31b is arranged at a wall surface of the housing 30 on the rear side in the travel direction. The windows 31a, 31b are inclined at the Brewster angle with respect to the travel direction of the laser light so that P-polarized light of the laser light is suppressed from being reflected. The output surfaces of the windows 31a, 31b are flat surfaces.

The electrodes 32a, 32b are arranged to face each other at the internal space of the housing 30, and the longitudinal direction of the electrodes 32a, 32b are along the travel direction of the light generated by the high voltage applied between the electrode 32a and the electrode 32b. The space between the electrode 32a and the electrode 32b in the housing 30 is sandwiched by the window 31a and the window 31b. The electrodes 32a, 32b are discharge electrodes for exciting the laser medium by glow discharge. In the present example, the electrode 32a is the cathode and the electrode 32b is the anode.

The electrode 32a is supported by the insulating portion 33. The insulating portion 33 blocks an opening formed in the housing 30. The insulating portion 33 includes an insulator. Further, the feedthrough 34 made of conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36.

The charger 41 is a DC power source device that charges a capacitor (not shown) provided in the pulse power module 43 with a predetermined voltage. The charger 41 is arranged outside the housing 30 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrodes 32a, 32b. When the high voltage is applied, discharge occurs between the electrode 32a and the electrode 32b. The energy of the discharge excites the laser medium in the housing 30. When the excited laser gas shifts to a ground level, light is emitted, and the emitted light is transmitted through the windows 31a, 31b and is output to the outside of the housing 30.

The line narrowing module 60 includes a housing 65, and a prism 61, a grating 63, and a rotation stage (not shown) arranged at the internal space of the housing 65. An opening is formed in the housing 65, and the housing 65 is connected to the rear side of the housing 30 via the opening.

The prism 61 expands the beam width of the light output from the window 31b and causes the light to be incident on the grating 63. The prism 61 also reduces the beam width of the light reflected from the grating 63 and returns the light to the internal space of the housing 30 through the window 31b. The prism 61 is supported by the rotation stage and is rotated by the rotation stage. The incident angle of the light with respect to the grating 63 is changed by the rotation of the prism 61. Therefore, by rotating the prism 61, the wavelength of the light returning from the grating 63 to the housing 30 via the prism 61 can be selected. Although FIG. 2 shows an example in which one prism 61 is arranged, two or more prisms may be arranged.

The surface of the grating 63 is configured of a material having a high reflectance, and a large number of grooves are formed on the surface at predetermined intervals. The grating 63 is a dispersive optical element. The sectional shape of each groove is, for example, a right-angled triangle. The light incident on the grating 63 from the prism 61 is reflected by these grooves and diffracted in a direction corresponding to the wavelength of the light. The grating 63 is arranged in the Littrow arrangement, which causes the incident angle of the light incident on the grating 63 from the prism 61 to coincide with the diffraction angle of the diffracted light having a desired wavelength. Thus, light having a desired wavelength returns to the housing 30 via the prism 61.

The output coupling mirror 70 faces the window 31a, transmits a part of the laser light output from the window 31a, and reflects another part thereof to return to the internal space of the housing 30 through the window 31a. The output coupling mirror 70 is fixed to a holder (not shown) and is arranged at the internal space of the housing 110.

The grating 63 and the output coupling mirror 70 arranged with the housing 30 interposed therebetween configure a Fabry-Perot resonator, and the housing 30 is arranged on the optical path of the resonator. Accordingly, the resonator causes the light to resonate between both sides sandwiching the chamber device CH1.

The optical transmission unit 141 includes high reflection mirrors 141b, 141c as a main configuration. The high reflection mirrors 141b, 141c are respectively fixed to holders (not shown) with inclination angles thereof adjusted, and are arranged at the internal space of the housing 110. The high reflection mirrors 141b, 141c highly reflect the laser light. The high reflection mirrors 141b, 141c are arranged on the optical path of the laser light from the output coupling mirror 70. The laser light is reflected by the high reflection mirrors 141b, 141c and travels to a rear mirror 371 of the amplifier 160. At least a part of the laser light is transmitted through the rear mirror 371.

The amplifier 160 amplifies the energy of the laser light output from the laser oscillator 130. The basic configuration of the amplifier 160 is substantially the same as that of the laser oscillator 130. In order to distinguish the components of the amplifier 160 from the components of the laser oscillator 130, the chamber device, the housing, the pair of windows, the pair of electrodes, the insulating portion, the feedthrough, the electrode holder portion, the charger, the pulse power module, and the output coupling mirror of the amplifier 160 are described as a chamber device CH3, a housing 330, a pair of windows 331a, 331b, a pair of electrodes 332a, 332b, an insulating portion 333, a feedthrough 334, an electrode holder portion 336, a charger 341, a pulse power module 343, and an output coupling mirror 370. The electrodes 332a, 332b cause discharge for amplifying the laser light from the laser oscillator 130. Similarly to the pulse power module 43, the pulse power module 343 is a voltage application circuit.

The amplifier 160 is mainly different from the laser oscillator 130 in that the line narrowing module 60 is not included and the rear mirror 371 and a beam expander 400 are included.

The rear mirror 371 is provided between the high reflection mirror 141c and the window 331b and faces to both thereof. The rear mirror 371 transmits a part of the laser light from the laser oscillator 130 toward the space between the electrodes 332a, 332b, and reflects a part of the laser light amplified by the electrodes 332a, 332b toward the space between the electrodes 332a, 332b.

The output coupling mirror 370 is arranged on the side opposite to the rear mirror 371 with respect to the chamber device CH3, and the beam expander 400 is arranged between the chamber device CH3 and the output coupling mirror 370. The beam expander 400 of the present example includes two prisms 401, 402. The prism 401 expands the beam width of the laser light output from the chamber device CH3. The prism 402 further expands the beam width of the light whose beam width has been expanded by the prism 401, and outputs the light toward the output coupling mirror 370. Further, the prism 402 reduces the beam width of the reflection light from the output coupling mirror 370, and the prism 401 further reduces the beam width of the light whose beam width has been reduced by the prism 402, and returns the light to the internal space of the housing 330 through the window 331a. The direction in which the prisms 401, 402 expand and reduce the beam width is a direction perpendicular to the direction in which the electrodes 332a, 332b face each other and to the optical axis of the light.

The surface of the output coupling mirror 370 on the beam expander 400 side is coated with a partial reflection film having a predetermined reflectance. The output coupling mirror 370 reflects a part of the laser light from the chamber device CH3 with the beam width thereof expanded by the beam expander 400 toward the beam expander 400, and transmits another part of the laser light.

The output coupling mirror 370 may have a circular shape. The surface of the output coupling mirror 370 on the beam expander 400 side and the surface opposite to the surface may be flat surfaces. Configurations of the rear mirror 371 and the output coupling mirror 70 are similar to that of the output coupling mirror 370.

The rear mirror 371 and the output coupling mirror 370 arranged with the housing 330 interposed therebetween configure a resonator in which the laser light amplified by the electrodes 332a, 332b resonates. The housing 330 and the beam expander 400 are arranged on the optical path of the resonator. The laser light output from the window 331a of the housing 330 is incident on the output coupling mirror 370 via the beam expander 400, and reflected by the output coupling mirror 370. The laser light reflected by the output coupling mirror 370 returns to the internal space of the housing 330 via the beam expander 400 and the window 331b, and is output from the window 331a. The laser light output from the window 331a is reflected by the rear mirror 371 and returns to the internal space of the housing 330 through the window 331b. Thus, the laser light output from the housing 330 reciprocates between the rear mirror 371 and the output coupling mirror 370. The reciprocating laser light is amplified every time the laser light passes through a laser gain space between the electrode 332a and the electrode 332b. That is, the resonator resonates light between both sides sandwiching the chamber device CH3, and the output coupling mirror 370 is arranged on one side of sandwiching the chamber device CH3. A part of the amplified laser light is transmitted through the output coupling mirror 370. The laser light transmitted through the output coupling mirror 370 travels to the detection unit 153.

The detection unit 153 includes a beam splitter 153b and an optical sensor 153c as a main configuration.

The beam splitter 153b is arranged on the optical path of the laser light transmitted through the output coupling mirror 370. The beam splitter 153b transmits the laser light transmitted through the output coupling mirror 370 to an output window 173 at a high transmittance, and reflects a part of the pulse laser light toward a light receiving surface of the optical sensor 153c.

The optical sensor 153c measures the pulse energy of the laser light incident on the light receiving surface of the optical sensor 153c. The optical sensor 153c is electrically connected to the processor 190, and outputs a signal indicating the measured pulse energy to the processor 190. The processor 190 controls the voltage to be applied to the electrodes 32a, 32b of the amplifier 160 based on the signal.

The output window 173 is provided on the side opposite to the output coupling mirror 370 with respect to the beam splitter 153b of the detection unit 153. The output window 173 is provided in a wall of the housing 110. The light transmitted through the beam splitter 153b is output from the output window 173 to the exposure apparatus 200 outside the housing 110. The laser light is, for example, pulse laser light having a center wavelength of 193.4 nm.

The display unit 180 is a monitor that displays a state of control by the processor 190 based on a signal from the processor 190. The display unit 180 may be arranged outside the housing 110.

The processor 190 of the present disclosure is a processing device including a storage device in which a control program is stored and a central processing unit (CPU) that executes the control program. The processor 190 is specifically configured or programmed to perform various processes included in the present disclosure. The processor 190 controls the entire gas laser device 100. The processor 190 is electrically connected to an exposure processor (not shown) of the exposure apparatus 200, and transmits and receives various signals to and from the exposure processor.

The laser gas exhaust device 701 and the laser gas supply device 703 are electrically connected to the processor 190. The laser gas exhaust device 701 includes an exhaust pump (not shown), and exhausts the laser gas from the internal spaces of the housings 30, 330 via a pipe by suction of the exhaust pump according to a control signal from the processor 190. The laser gas supply device 703 supplies the laser gas from a laser gas supply source (not shown) arranged outside the housing 110 to the internal spaces of the housings 30, 330 via a pipe according to a control signal from the processor 190.

### 2.2 Operation

Next, operation of the gas laser device 100 of the comparative example will be described.

In a state before the gas laser device 100 outputs the laser light, the laser gas is supplied from the laser gas supply device 703 to the internal spaces of the housings 30, 330.

When the gas laser device 100 outputs the laser light, the processor 190 receives a signal indicating a target energy Et and a light emission trigger signal from the exposure processor (not shown) of the exposure apparatus 200. The target energy Et is a target value of the energy of the laser light to be used in the exposure process. The processor 190 sets a predetermined charge voltage to the charger 41 so that an energy E becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, and is amplified every time passing through the discharge space at the internal space of the housing 30, so that laser oscillation occurs. A part of the laser light is transmitted through the output coupling mirror 70, is reflected by the high reflection mirrors 141b, 141c, is transmitted through the rear mirror 371 and the window 31b, and travels into the housing 330.

The processor 190 turns ON the switch of the pulse power module 343 so that discharge occurs when the laser light from the laser oscillator 130 travels to the discharge space in the housing 330. That is, the processor 190 controls the pulse power module 343 such that a high voltage is applied to the electrodes 332a, 332b after a predetermined delay time elapses from the timing at which the switch of the pulse power module 43 is turned ON.

Thus, the laser light having entered the amplifier 160 is amplified in the amplifier 160. Further, the laser light having traveled through the internal space of the housing 330 travels to the output coupling mirror 370 via the window 331a and the beam expander 400 as described above, and is reflected by the output coupling mirror 370. The laser light reflected by the output coupling mirror 370 travels through the internal space of the housing 330 via the beam expander 400 and the window 331a, and is output from the window 331b. The light output from the window 331b is reflected by the rear mirror 371 and travels through the internal space of the housing 330 via the window 331b. Thus, the laser light having a predetermined wavelength reciprocates between the rear mirror 371 and the output coupling mirror 370. The laser light is amplified every time passing through the discharge space at the internal space of the housing 330, and a part of the laser light becomes amplified laser light.

The amplified laser light from the amplifier 160 is transmitted through the output coupling mirror 370 and travels to the beam splitter 153b.

A part of the amplified laser light traveling to the beam splitter 153b is transmitted through the beam splitter 153b and the output window 173 and travels to the exposure apparatus 200, while another part is reflected by the beam splitter 153b and travels to the optical sensor 153c.

The optical sensor 153c measures the energy E of the received amplified laser light. The optical sensor 153c outputs a signal indicating the measured energy E to the processor 190. The processor 190 performs feedback control on the charge voltages of the chargers 41, 341 so that a difference ΔE between the energy E and the target energy Et is within an allowable range. When the difference ΔE is within the allowable range, the laser light is transmitted through the beam splitter 153b and the output window 173 and enters the exposure apparatus 200.

### 2.3 Problem

In the comparative example, the beam expander 400 expands the beam width of the laser light output from the chamber device CH3 by the two prisms 401, 402, and outputs the light toward the output coupling mirror 370. Therefore, the energy density of the laser light incident on the output coupling mirror 370 can be reduced, and deterioration over time of the output coupling mirror 370 can be suppressed. However, since the prism 401 and the prism 402 are transmissive optical elements, there is a concern that they deteriorate over time by transmission light.

Therefore, in the following embodiments, a gas laser device capable of suppressing deterioration over time is exemplified.

### 3. Description of Gas Laser Device of First Embodiment

Next, the gas laser device 100 of a first embodiment will be described. Any component same as that described above is denoted by an identical reference sign, and duplicate description thereof is omitted unless specific description is needed. Further, in some drawings, a part of a member may be omitted or simplified for easy viewing.

### 3.1 Configuration

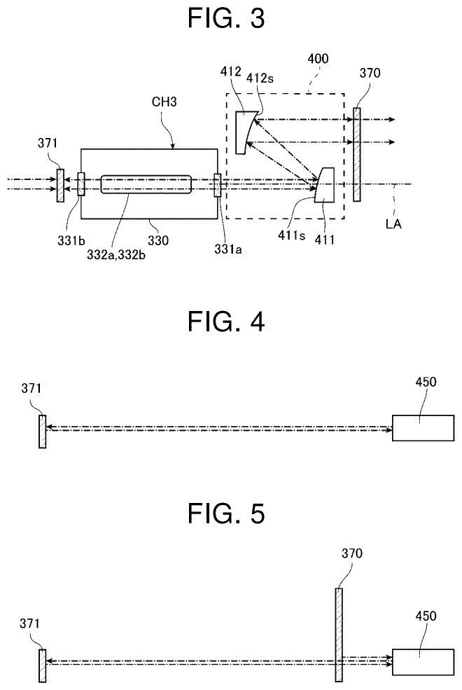

FIG. 3 is a schematic diagram showing a schematic configuration example of the amplifier 160 according to the first embodiment, and is a schematic diagram of the amplifier 160 viewed from the direction in which the pair of electrodes 332a, 332b face each other. Further, in FIG. 3, the internal configuration of the chamber device CH3 is shown.

The amplifier 160 of the present embodiment is mainly different from the amplifier 160 of the comparative example in that the beam expander 400 includes a convex mirror 411 and a concave mirror 412.

The convex mirror 411 includes a reflection surface 411s that reflects light, and is fixed to a holder (not shown) so as to reflect the light toward the concave mirror 412. The concave mirror 412 includes a reflection surface 412s that reflects light, and is fixed to a holder (not shown) so as to reflect the light toward the output coupling mirror 370. The convex mirror 411 reflects the laser light from the chamber device CH3 toward the concave mirror 412, and the concave mirror 412 reflects the laser light from the convex mirror 411 toward the output coupling mirror 370. Further, the concave mirror 412 reflects the laser light reflected by the output coupling mirror 370 toward the convex mirror 411, the convex mirror 411 reflects the light reflected by the concave mirror 412 toward the chamber device CH3, and the light returns to the internal space of the housing 330 through the window 331a.

In the present embodiment, the convex mirror 411 and the concave mirror 412 are columnar members in which the electrodes 332a, 332b face each other. The sectional shape of the reflection surface 411s of the convex mirror 411 in plane perpendicular to the direction in which the electrodes 332a, 332b face each other forms a parabola. The sectional shape of the reflection surface 411s in a plane along the direction in which the electrodes 332a, 332b face each other forms a straight line. The sectional shape of the reflection surface 412s of the concave mirror 412 in the plane perpendicular to the direction in which the electrodes 332a, 332b face each other forms a parabola. The sectional shape of the reflection surface 412s in a plane along the direction in which the electrodes 332a, 332b face each other forms a straight line. The focal point of the reflection surface 411s and the focal point of the reflection surface 412s substantially overlap each other. That is, the positions of the convex mirror 411 and the concave mirror 412 are adjusted as described above.

In the present specification and claims, the term “vertical” refers to a state in which the angle formed is 85 degrees or more and 95 degrees or less, and the term “parallel” refers to a state in which the angle formed is 5 degrees or less.

In the present embodiment, the output coupling mirror 370 has a rectangular shape elongated in the direction perpendicular to the direction in which the electrodes 332a, 332b face each other. The output coupling mirror 370 extends from a position on which the laser light reflected by the concave mirror 412 is incident to a position at which an optical axis LA of the laser light from the chamber device CH3 toward the convex mirror 411 intersects. Therefore, when the convex mirror 411 is not arranged, the laser light from the chamber device CH3 is incident on the output coupling mirror 370. Here, the shape of the output coupling mirror 370 is not limited, and may be, for example, a circular shape.

### 3.2 Operation

When the laser light is output from the window 331a of the housing 330, the laser light is reflected by the convex mirror 411 toward the concave mirror 412. The sectional shape of the reflection surface 411s of the convex mirror 411 in the plane perpendicular to the direction in which the electrodes 332a, 332b face each other forms a parabola. Therefore, the beam width of the laser light reflected by the convex mirror 411 is expanded in the direction perpendicular to the direction in which the electrodes 332a, 332b face each other and to the optical axis LA of the laser light. The laser light having the expanded beam width is reflected by the concave mirror 412 toward the output coupling mirror 370. The sectional shape of the reflection surface 412s of the concave mirror 412 in the plane perpendicular to the direction in which the electrodes 332a, 332b face each other forms a parabola, and the focal point of the reflection surface 411s and the focal point of the reflection surface 412s substantially overlap each other. Therefore, the laser light reflected by the concave mirror 412 is collimated so that the expanded beam width becomes constant, and is incident on the output coupling mirror 370.

Further, the laser light reflected by the output coupling mirror 370 is reflected by the concave mirror 412 toward the convex mirror 411. The beam width of the laser light is reduced in the direction perpendicular to the direction in which the electrodes 332a, 332b face each other. The laser light having the reduced beam width is reflected by the convex mirror 411 toward the window 331a. The laser light is collimated so that the expanded beam width becomes constant, and is returned to the internal space of the housing 330 through the window 331a.

### 3.3 Effect

The beam expander 400 of the present embodiment includes the convex mirror 411 and the concave mirror 412. The convex mirror 411 reflects the laser light to expand the beam width of the laser light from the chamber device CH3. The concave mirror 412 collimates the laser light so that the expanded beam width of the laser light reflected by the convex mirror 411 becomes constant, and reflects the laser light to the output coupling mirror 370. In general, an optical element that reflects light tends to be less likely to deteriorate over time than an optical element that transmits light. Therefore, according to the gas laser device 100 of the present embodiment, as compared with the case in which the beam expander 400 includes the prisms 401, 402 that transmit light, deterioration over time of the beam expander 400 can be suppressed, and as a result, deterioration over time of the gas laser device 100 can be suppressed.

In the present embodiment, the sectional shape of each of the reflection surfaces 411s, 412s in the plane perpendicular to the direction in which the electrodes 332a, 332b face each other forms a parabola, but is not limited thereto. These sectional shapes may be, for example, arcs. In this case, the convex mirror 411 and the concave mirror 412 are arranged such that the focal point of the reflection surface 411s and the focal point of the reflection surface 412s overlap each other.

In the present embodiment, the convex mirror 411 reflects the laser light to expand the beam width of the laser light output from the chamber device CH3 in the direction perpendicular to the direction in which the electrodes 332a, 332b face each other and to the optical axis LA of the laser light. However, the direction in which the beam width is expanded by the convex mirror 411 is not limited thereto. The beam width may be expanded in a plurality of directions, and the beam diameter may be enlarged. In this case, for example, each of the reflection surface 411s and the reflection surface 412s is formed as a part of a paraboloid of revolution or a spherical surface.

Further, in the present embodiment, as described above, the output coupling mirror 370 extends from the position on which the laser light reflected by the concave mirror 412 is incident to the position at which the optical axis LA of the laser light intersects. Accordingly, the output coupling mirror 370 and the beam expander 400 can be arranged as follows, for example.

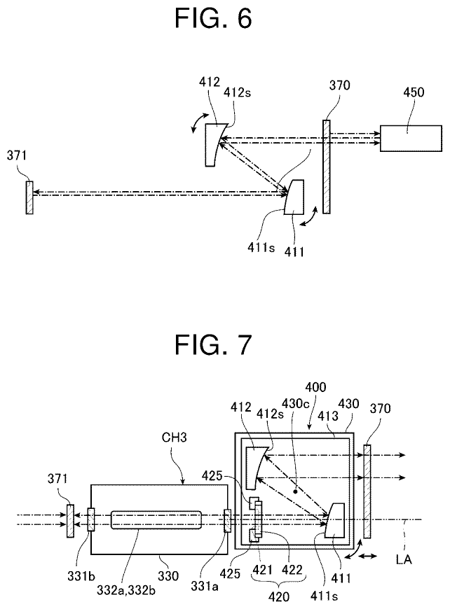

FIG. 4 is a diagram showing a state of preparation before the output coupling mirror 370 is arranged, FIG. 5 is a diagram showing a state of the output coupling mirror 370 being arranged, and FIG. 6 is a diagram showing a state of the beam expander 400 being arranged.

As shown in FIG. 4, first, light is output from an autocollimator 450 toward the rear mirror 371 while the chamber device CH3 is not arranged. The angle between the optical axis of the light output from the autocollimator 450 and the optical axis of the light reflected by the rear mirror 371 and incident on the autocollimator 450 is measured by the autocollimator 450. The orientation of the autocollimator 450 with respect to the rear mirror 371 is adjusted so that the angle becomes zero.

Next, as shown in FIG. 5, the output coupling mirror 370 is arranged at a design position, and light is output from the autocollimator 450. The angle between the optical axis of the light output from the autocollimator 450 and the optical axis of the light reflected by the output coupling mirror 370 and incident on the autocollimator 450 is measured by the autocollimator 450. The orientation of the output coupling mirror 370 with respect to the rear mirror 371 is adjusted so that the angle becomes zero. As described above, since the output coupling mirror 370 extends to the position to intersect the optical axis LA, the autocollimator 450 does not need to be moved, and the output coupling mirror 370 can be accurately oriented with respect to the rear mirror 371.

Next, as shown in FIG. 6, the beam expander 400 is arranged at a design position. The autocollimator 450 is moved to a position where the light output from the autocollimator 450 and returning from the concave mirror 412 is incident on the autocollimator 450. The angle between the optical axis of the light output from the autocollimator 450 and the optical axis of the light reflected by the output coupling mirror 370 and incident on the autocollimator 450 is measured by the autocollimator 450. The orientation of the autocollimator 450 with respect to the rear mirror 371 is adjusted so that the angle becomes zero. Thereafter, the angle between the optical axis of the light output from the autocollimator 450 and the optical axis of f the light returning from the concave mirror 412 to the autocollimator 450 is measured by the autocollimator 450. The positions of the convex mirror 411 and the concave mirror 412 and orientations thereof with respect to the output coupling mirror 370 are adjusted so that the angle becomes zero. Thus, the output coupling mirror 370, the convex mirror 411, and the concave mirror 412 can be arranged.

### 4. Description of Gas Laser Device of Second Embodiment

Next, the gas laser device 100 of a second embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

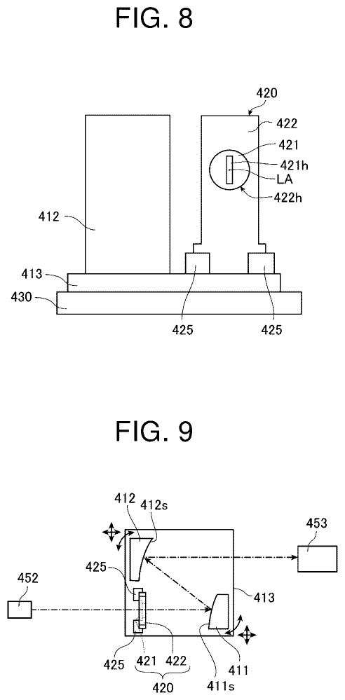

FIG. 7 is a schematic diagram showing a schematic configuration example of the amplifier 160 of the present embodiment in the same manner as in FIG. 3, and FIG. 8 is a diagram showing the beam expander 400 shown in FIG. 7 as viewed from the chamber device CH3 side.

The amplifier 160 of the present embodiment is mainly different from the amplifier 160 of the first embodiment in that the beam expander 400 further includes a base member 413 and a drive mechanism 430. In FIGS. 7 and 8, a state in which a slit member 420 described later is arranged on the base member 413 is shown, but when the laser light is output from the gas laser device 100, the slit member 420 is removed.

The base member 413 of the present embodiment is a plate-shaped member extending in the direction parallel to the optical axis LA of the laser light from the chamber device CH3 toward the convex mirror 411. In the present embodiment, the base member 413 extends in the direction perpendicular to the direction in which the electrodes 332a, 332b face each other, but is not limited thereto. On one main surface of the base member 413, the convex mirror 411 and the concave mirror 412 are arranged. Further, the base member 413 is provided with a pair of positioning portions 425 capable of positioning the slit member 420 at a predetermined position.

The slit member 420 includes a main body portion 421 and a holding portion 422. The main body portion 421 is a plate-shaped member provided with a slit 421h being a through hole. The main body portion 421 has a circular shape, and the slit 421h has a rectangular shape elongated in the direction in which the electrodes 332a, 332b face each other. The holding portion 422 is a plate-shaped member provided with a through hole 422h to which the main body portion 421 can be fitted, and the main body portion 421 is held by the holding portion 422 by being fitted to the through hole 422h. Therefore, it can be understood that the slit member 420 is provided with the slit 421h. Here, the main body portion 421 and the holding portion 422 may be integrally formed, and the holding portion 422 may be provided with the slit 421h.

The pair of positioning portions 425 of the present embodiment are columnar members each having a substantially L-shaped cross section. The pair of positioning portions 425 can hold the slit member 420 by sandwiching the holding portion 422 of the slit member 420 from the direction perpendicular to the thickness direction. Further, the positioning portions 425 can be brought into contact with one main surface of the holding portion 422. The positioning portions 425 abut on the one main surface of the holding portion 422, and the side surface of the holding portion 422 on the base member 413 side abuts on the main surface of the base member 413, whereby the slit member 420 is positioned at a predetermined position. The predetermined position is a position on the base member 413 on the chamber device CH3 side with respect to the convex mirror 411. When the slit member 420 is arranged at the predetermined position, the optical axis LA passes through the slit 421h.

The drive mechanism 430 of the present embodiment includes a rotation mechanism capable of rotating the base member 413 about an axis 430c perpendicular to the extending direction of the base member 413, and a movement mechanism capable of moving the base member 413 in the direction parallel to the extending direction of the base member 413. In the drive mechanism 430 of the present embodiment, the rotation mechanism is mounted on the movement mechanism, and the base member 413 is mounted on the rotation mechanism. The axis 430c overlaps the center of gravity of the base member 413, but the position of the axis 430c is not limited thereto.

### 4.2 Effect

The beam expander 400 of the present embodiment includes the plate-shaped base member 413 extending in the direction parallel to the optical axis LA and having the main surface on which the convex mirror 411 and the concave mirror 412 are arranged. Therefore, by arranging the base member 413 at the design position, the convex mirror 411 and the concave mirror 412 can be arranged at the design positions. Accordingly, the convex mirror 411 and the concave mirror 412 can be easily arranged at the design positions as compared with the case in which the convex mirror 411 and the concave mirror 412 are arranged individually.

Further, in the present embodiment, the base member 413 is provided with the positioning portions 425 capable of positioning the slit member 420 at the predetermined position when the slit member 420 provided with the slit 421h is arranged at the predetermined position. The predetermined position is a position of the base member 413 on the chamber device CH3 side with respect to the convex mirror 411. When the slit member 420 is arranged at the predetermined position, the optical axis LA passes through the slit 421h. Accordingly, the beam expander 400 can be arranged as follows, for example.

FIG. 9 is a diagram showing a state of the convex mirror 411 and the concave mirror 412 being arranged on the base member 413.

First, as shown in FIG. 9, the slit member 420 is arranged at the position positioned by the positioning portions 425 on the base member 413, and the convex mirror 411 and the concave mirror 412 are arranged at the design positions. The slit member 420 is irradiated with parallel light whose propagation direction is perpendicular to the slit member 420 from an adjustment light source 452. The entire slit 421h is located within the irradiation spot of the light in the slit member 420. Accordingly, parallel light having an outer shape substantially the same as the shape of the slit 421h is reflected by the convex mirror 411. The light reflected by the convex mirror 411 and reflected by the concave mirror 412 is measured by a beam measurement device 453. Examples of the beam measurement device 453 include an optical position sensor, a share plate, a beam profiler, and a wavefront sensor. The beam measurement device 453 measures the incident position of the light from the concave mirror 412 and the beam size and divergence angle of the light. The beam size is the magnitude of the light reflected and collimated by the concave mirror 412, and the divergence angle indicates the degree of collimation of the light reflected by the concave mirror 412. Based on the measurement result, the positions of the convex mirror 411 and the concave mirror 412 and the orientations thereof with respect to the slit member 420 are adjusted so that the incident position of the light from the concave mirror 412 at the beam measurement device 453 becomes a defined position, the beam size of the light becomes a defined size, and the divergence angle falls within a defined range. Then, the base member 413 on which the convex mirror 411 and the concave mirror 412 are arranged is mounted on the drive mechanism 430.

Next, the output coupling mirror 370 is arranged at the design position while the chamber device CH3 is not arranged. Next, as in the first embodiment shown in FIGS. 4 and 5, the orientation of the output coupling mirror 370 with respect to the rear mirror 371 is adjusted. Next, the beam expander 400 with the convex mirror 411 and the concave mirror 412 adjusted is arranged at the design position. As in the first embodiment shown in FIG. 6, the angle between the optical axis of the light output from the autocollimator 450 and the optical axis of the light returning from the concave mirror 412 to the autocollimator 450 is measured by the autocollimator 450. The position and orientation of the base member 413 with respect to the rear mirror 371 are adjusted by the drive mechanism 430 so that the angle becomes zero. Thus, the beam expander 400 can be arranged. Here, the position and orientation of the base member 413 may not be adjusted, and the beam expander 400 may not include the drive mechanism 430. For example, a working space may be difficult to be secured, and the positions and orientations of the convex mirror 411 and the concave mirror 412 arranged in the gas laser device 100 may be difficult to be adjusted. However, in the present embodiment, the beam expander 400 with the relative positions and orientations of the convex mirror 411 and the concave mirror 412 adjusted can be arranged. Therefore, compared with the case in which the beam expander 400 does not include the base member 413, the positions and orientations of the convex mirror 411 and the concave mirror 412 can be easily adjusted to the correct positions and orientations.

The slit member 420 is positioned at the predetermined position by the pair of positioning portions 425 in the present embodiment, but the positioning portion for positioning the slit member 420 at the predetermined position is not limited thereto. For example, the positioning portion may be an annular member causing a part of the slit member 420 to be inserted into the internal space thereof to hold the slit member 420.

Although the positioning portions 425 are provided in the base member 413 of the present embodiment, the positioning portions 425 may not be provided in the base member 413.

The slit 421h of the slit member 420 of the present embodiment has a rectangular shape, but is not limited thereto. Another example of the slit 421h will be described with reference to a modification described below.

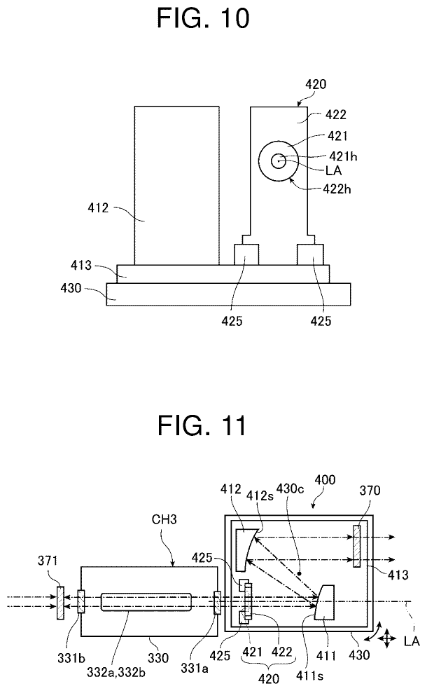

FIG. 10 is a diagram showing the beam expander 400 in the modification of the second embodiment viewed from the chamber device CH3 side. In FIG. 10, a state in which the slit member 420 is arranged on the base member 413 is shown, but when the laser light is output from the gas laser device 100, the slit member 420 is removed.

The slit member 420 of the present modification is mainly different from the slit member 420 of the second embodiment in that the slit 421h has a circular shape. When the slit member 420 is arranged at a predetermined position positionable by the pair of positioning portions 425, the optical axis LA of the laser light from the chamber device CH3 toward the convex mirror 411 passes through the slit 421h. Even with the slit member 420 of the present modification, the convex mirror 411 and the concave mirror 412 can be arranged on the base member 413 in the same manner as in the second embodiment. Here, the slit 421h is not limited thereto. The slit 421h may have the same shape as the outer shape of the laser light output from the chamber device CH3, and the size of the laser light and the size of the slit 421h may be the same. In addition, the slit 421h may have an elliptical shape to form a circular beam at the beam measurement device 453.

### 5. Description of Gas Laser Device of Third Embodiment

Next, the gas laser device 100 of a third embodiment will be described. Any component same as that described above is denoted by an identical reference sign, and duplicate description thereof is omitted unless specific description is needed. Further, in some drawings, a part of a member may be omitted or simplified for easy viewing.

### 5.1 Configuration

FIG. 11 is a schematic view showing a schematic configuration example of the amplifier 160 of the present embodiment in the same manner as in FIG. 3. The amplifier 160 of the present embodiment is mainly different from the amplifier 160 of the second embodiment in that the output coupling mirror 370 is arranged on the base member 413. In FIG. 11, a state in which the slit member 420 is arranged on the base member 413 is shown, but when the laser light is output from the gas laser device 100, the slit member 420 is removed.

The output coupling mirror 370 of the present embodiment is arranged on the main surface of the base member 413. However, the output coupling mirror 370 may be arranged, for example, on the side opposite to the output coupling mirror 370, of the side surfaces of the base member 413. In this case, the side surface of the base member 413 and the surface of the output coupling mirror 370 on the rear mirror 371 side face each other. Further, the output coupling mirror 370 does not extend to the position intersecting the optical axis LA, but may extend to the position intersecting the optical axis LA.

### 5.2 Effect

The beam expander 400 of the present embodiment includes the drive mechanism 430, and the output coupling mirror 370, the convex mirror 411, and the concave mirror 412 are arranged on the base member 413. Accordingly, the beam expander 400 can be arranged as follows, for example.

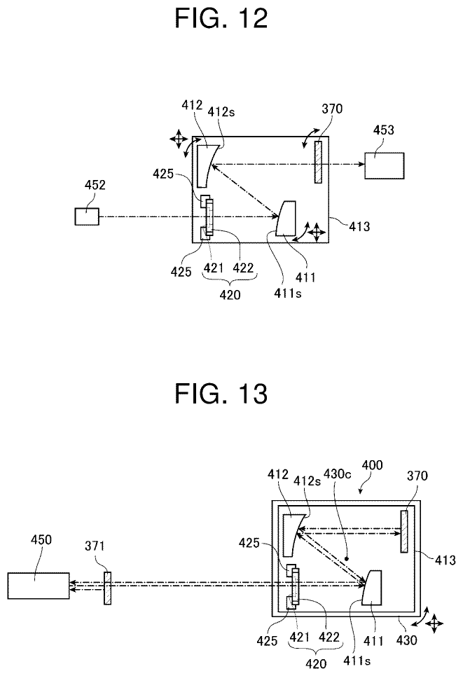

FIG. 12 is a diagram showing a state of the output coupling mirror 370, the convex mirror 411, and the concave mirror 412 being arranged on the base member 413, and FIG. 13 is a diagram showing a state of the beam expander 400 being arranged.

First, as shown in FIG. 12, the slit member 420 is arranged at the position positioned by the positioning portions 425 on the base member 413, and the output coupling mirror 370, the convex mirror 411, and the concave mirror 412 are arranged at the design positions. The orientation of the output coupling mirror 370 is adjusted so that the slit member 420 and the output coupling mirror 370 are parallel to each other. Next, parallel light whose propagation direction is perpendicular to the slit member 420 is radiated from the adjustment light source 452 to the slit member 420. The entire slit 421h is located within the irradiation spot of the light in the slit member 420. Accordingly, parallel light having an outer shape substantially the same as the shape of the slit 421h is reflected by the convex mirror 411. The light reflected by the convex mirror 411 and reflected by the concave mirror 412 is measured by the beam measurement device 453. The beam measurement device 453 measures the incident position of the light from the concave mirror 412 and the beam size and divergence angle of the light. Based on the measurement result, the positions of the convex mirror 411 and the concave mirror 412 and the orientations thereof with respect to the slit member 420 are adjusted so that the incident position of the light from the concave mirror 412 at the beam measurement device 453 becomes a defined position, the beam size of the light becomes a defined size, and the divergence angle falls within a defined range. Then, the base member 413 on which the convex mirror 411 and the concave mirror 412 are arranged is mounted on the drive mechanism 430.

Next, as shown in FIG. 13, the beam expander 400 is arranged at the design position while the chamber device CH3 is not arranged. The autocollimator 450 is arranged on the side opposite to the beam expander 400 with respect to the rear mirror 371 so that the output light enters the slit 421h through the rear mirror 371. The angle between the optical axis of the light output from the autocollimator 450 and the optical axis of the light reflected by the rear mirror 371 and incident on the autocollimator 450 is measured by the autocollimator 450. The orientation of the autocollimator 450 is adjusted so that the angle becomes zero and the light transmitted through the rear mirror 371 enters the slit 421h. Next, the angle between the optical axis of the light output from the autocollimator 450 and the optical axis of the light returning from the beam expander 400 to the autocollimator 450 is measured by the autocollimator 450. The drive mechanism 430 adjusts the position of the base member 413 and the rotational angle about the axis 430c so that the angle becomes zero. Thus, the output coupling mirror 370 and the beam expander 400 can be arranged. Further, according to the gas laser device 100 of the present embodiment, even without providing drive mechanisms respectively for adjusting the positions and orientations of the output coupling mirror 370, the convex mirror 411, and the concave mirror 412, the positions and orientations thereof can be easily set to accurate positions and orientations.

Although the positioning portions 425 are provided in the base member 413 of the present embodiment, the positioning portions 425 may not be provided in the base member 413.

Although the beam expander 400 of the present embodiment includes the drive mechanism 430, the drive mechanism may not be included.

The drive mechanism 430 of the present embodiment includes the rotation mechanism capable of rotating the base member 413 about the axis 430c, and the movement mechanism capable of moving the base member 413 in the direction parallel to the extending direction of the base member 413, but is not limited thereto. The drive mechanism 430 may include at least one of the above-described rotation mechanism and the above-described movement mechanism. Another example of the beam expander 400 will be described with reference to a modification described below.

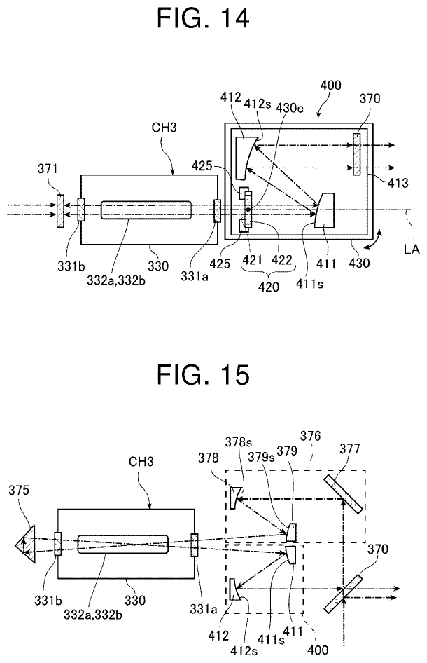

FIG. 14 is a schematic view showing a schematic configuration example of the amplifier 160 of a modification of the third embodiment in the same manner as in FIG. 3. The drive mechanism 430 of the present modification is mainly different from the drive mechanism 430 of the third embodiment in being configured of a rotation mechanism capable of rotating the base member 413 about the axis 430c perpendicular to the extending direction of the base member 413. In FIG. 14, a state in which the slit member 420 is arranged on the base member 413 is shown, but when the laser light is output from the gas laser device 100, the slit member 420 is removed.

In the present modification, the axis 430c is an axis that passes through the center of the slit 421h and is perpendicular to the extending direction of the base member 413 when the slit member 420 is arranged at the predetermined position. Since the drive mechanism 430 includes the rotation mechanism described above, the beam expander 400 can be arranged in the same manner as in the third embodiment even when the drive mechanism 430 does not include the movement mechanism capable of moving the base member 413 in the direction parallel to the extending direction of the base member 413. Therefore, according to the present modification, the configuration of the beam expander 400 can be simplified.

### 6. Description of Gas Laser Device of Fourth Embodiment

Next, the gas laser device 100 of a fourth embodiment will be described. Any component same as that described above is denoted by an identical reference sign, and duplicate description thereof is omitted unless specific description is needed. Further, in some drawings, a part of a member may be omitted or simplified for easy viewing.

### 6.1 Configuration

FIG. 15 is a schematic view showing a schematic configuration example of the amplifier 160 of the present embodiment in the same manner as in FIG. 3. The amplifier 160 of the present embodiment is mainly different from the amplifier 160 of the first embodiment in that the resonator is a ring resonator.

Further, the amplifier 160 of the present embodiment is different from the amplifier 160 of the first embodiment in including a prism 375 instead of the rear mirror 371 and including an optical transmission unit 376.

In the present embodiment, the laser light from the laser oscillator 130 is incident on the output coupling mirror 370, and the output coupling mirror 370 transmits a part of the laser light toward the optical transmission unit 376, and reflects another part of the laser light toward the detection unit 153. Further, the output coupling mirror 370 reflects a part of the laser light output from the chamber device CH3 with the beam width thereof expanded by the beam expander 400 toward the optical transmission unit 376, and transmits another part of the laser light toward the detection unit 153.

The optical transmission unit 376 is arranged on the output coupling mirror 370 side with respect to the chamber device CH3, and includes a reflection mirror 377, a resonator concave mirror 378, and a resonator convex mirror 379. Each of the reflection mirror 377, the resonator concave mirror 378, and the resonator convex mirror 379 is fixed to a holder (not shown).

The reflection mirror 377 reflects the laser light from the output coupling mirror 370 toward the resonator concave mirror 378.

The resonator concave mirror 378 has a configuration similar to that of the concave mirror 412, and includes a reflection surface 378s having a configuration similar to that of the reflection surface 412s. The resonator concave mirror 378 reflects the laser light reflected by the reflection mirror 377 to reduce the beam width in the direction collimated by the concave mirror 412.

The resonator convex mirror 379 has a configuration similar to that of the convex mirror 411, and includes a reflection surface 379s having a configuration similar to that of the reflection surface 411s. The resonator convex mirror 379 reflects the laser light reflected by the resonator concave mirror 378 back to the chamber device CH3 to collimate the laser light so that the reduced beam width becomes constant. By the optical transmission unit 376 described above, the beam width of the laser light whose beam width is expanded by the beam expander 400 is substantially the same as the beam width before the beam width is expanded, and the laser light returns to the internal space of the housing 330 through the window 331a.

The prism 375 returns the laser light output from the window 331b of the housing 330 to the internal space of the housing 330 via the window 331b. Thus, the output coupling mirror 370, the prism 375, and the optical transmission unit 376 configure a ring resonator in which the laser light resonates.

### 6.2 Effect

Therefore, similarly to the gas laser apparatus of the first embodiment, according to the gas laser device 100 of the present embodiment, deterioration over time of the beam expander 400 can be suppressed, and as a result, deterioration over time of the gas laser device 100 can be suppressed.

The optical transmission unit 376 of the present embodiment includes the reflection mirror 377, the resonator concave mirror 378, and the resonator convex mirror 379, but is not limited thereto. For example, the laser light from the output coupling mirror 370 may be incident on the resonator concave mirror 378 without via the reflection mirror 377. In this case, for example, the laser light reflected by the resonator convex mirror 379 may be reflected toward the chamber device CH3 by a reflection mirror arranged between the resonator convex mirror 379 and the chamber device CH3. Further, the optical transmission unit 376 may include at least one prism instead of the resonator concave mirror 378 and the resonator convex mirror 379. In this case, the beam width, in the direction collimated by the concave mirror 412, of the laser light reflected by the reflection mirror 377 is reduced by the at least one prism to be substantially the same as the beam width before the beam width is expanded. Then, the laser light is returned to the internal space of the housing 330 through the window 331a.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device configured to amplify, using an amplifier, laser light output from a laser oscillator and output the laser light,
the amplifier including:
a chamber device including a pair of discharge electrodes facing each other and arranged at an internal space thereof through which the laser light from the laser oscillator passes and in which a laser gas is filled, and being configured to amplify the laser light from the laser oscillator by a voltage being applied between the pair of discharge electrodes;
a resonator configured to cause the laser light output from the chamber device to resonate between both sides sandwiching the chamber device; and
a beam expander,
the resonator including an output coupling mirror arranged on one side of the sides sandwiching the chamber device, and being configured to cause a part of the laser light output from the chamber device to be transmitted therethrough, and another part of the laser light output from the chamber device to be reflected back into the chamber device, and
the beam expander being arranged between the chamber device and the output coupling mirror, and including a convex mirror including a reflection surface reflecting the laser light output from the chamber device to expand a beam width of the laser light, and a concave mirror including a reflection surface reflecting the laser light reflected by the convex mirror toward the output coupling mirror to collimate the laser light so that the expanded beam width of the laser light becomes constant.

2. The gas laser device according to claim 1,
wherein the convex mirror reflects the laser light to expand the beam width of the laser light output from the chamber device in a direction perpendicular to a direction in which the discharge electrodes face each other and to an optical axis of the laser light.

3. The gas laser device according to claim 2,
wherein each of a sectional shape of the reflection surface of the convex mirror and the reflection surface of the concave mirror in a plane perpendicular to the direction in which the discharge electrodes face each other forms a parabola.

4. The gas laser device according to claim 1,
wherein the output coupling mirror extends to a position at which an optical axis of the laser light from the chamber device toward the convex mirror intersects.

5. The gas laser device according to claim 1,
wherein the beam expander further includes a plate-shaped base member extending in a direction parallel to an optical axis of the laser light from the chamber device toward the convex mirror and having a main surface on which the convex mirror and the concave mirror are arranged.

6. The gas laser device according to claim 5,
wherein the base member is provided with a positioning portion capable of positioning a slit member at a predetermined position when the slit member provided with a slit is arranged at the predetermined position of the base member on the chamber device side with respect to the convex mirror, and
the optical axis of the laser light from the chamber device toward the convex mirror passes through the slit of the slit member arranged at the predetermined position.

7. The gas laser device according to claim 6,
wherein the slit has a circular shape.

8. The gas laser device according to claim 6,
wherein the slit has a rectangular shape.

9. The gas laser device according to claim 5,
wherein the output coupling mirror is arranged on the base member.

10. The gas laser device according to claim 5,
wherein the beam expander further includes at least one of a rotation mechanism capable of rotating the base member about an axis perpendicular to an extending direction of the base member, and a movement mechanism capable of moving the base member in a direction parallel to the extending direction of the base member.

11. The gas laser device according to claim 6,
wherein the beam expander further includes a rotation mechanism capable of rotating the base member about an axis that passes through a center of the slit and is perpendicular to an extending direction of the base member when the slit member is to be arranged at the predetermined position.

12. The gas laser device according to claim 11,
wherein the output coupling mirror is arranged on the base member.

13. The gas laser device according to claim 1,
wherein the resonator is a Fabry-Perot resonator.

14. The gas laser device according to claim 1,
wherein the resonator is a ring resonator.

15. The gas laser device according to claim 14,
wherein the resonator further includes:
a resonator concave mirror arranged on the output coupling mirror side with respect to the chamber device, and including a reflection surface reflecting the laser light to reduce a beam width, of the laser light collimated by the concave mirror and reflected by the output coupling mirror, in a direction in which the laser light is collimated by the concave mirror, and
a resonator convex mirror arranged on the output coupling mirror side with respect to the chamber device, and including a reflection surface reflecting the laser light reflected by the resonator concave mirror back into the chamber device to collimate the laser light so that the reduced beam width becomes constant.

16. An electronic device manufacturing method, comprising:
generating pulse laser light using a gas laser device;
outputting the pulse laser light to an exposure apparatus; and
exposing a photosensitive substrate to the pulse laser light in the exposure apparatus to manufacture an electronic device,
the gas laser device being configured to amplify, using an amplifier, laser light output from a laser oscillator and output the laser light,
the amplifier including:
a chamber device including a pair of discharge electrodes facing each other and arranged at an internal space thereof through which the laser light from the laser oscillator passes and in which a laser gas is filled, and being configured to amplify the laser light from the laser oscillator by a voltage being applied between the pair of discharge electrodes;
a resonator configured to cause the laser light output from the chamber device to resonate between both sides sandwiching the chamber device; and
a beam expander,
the resonator including an output coupling mirror arranged on one side of the sides sandwiching the chamber device, and being configured to cause a part of the laser light output from the chamber device to be transmitted therethrough, and another part of the laser light output from the chamber device to be reflected back into the chamber device, and
the beam expander being arranged between the chamber device and the output coupling mirror, and including a convex mirror configured to reflect the laser light output from the chamber device to expand a beam width of the laser light, and a concave mirror configured to reflect the laser light reflected by the convex mirror toward the output coupling mirror to collimate the laser light so that the expanded beam width of the laser light becomes constant.
